(19) United States
(12) Patent Application Publication
(10) Pub. No.: US 2025/0299994 A1
(43) Pub. Date: Sep. 25, 2025

(54) METHOD FOR PRODUCING SEMICONDUCTOR DEVICE

(71) Applicant: Resonac Corporation, Minato-ku, Tokyo (JP)

(72) Inventors: Yuki MIYAMOTO, Minato-ku, Tokyo (JP); Haemil CHOI, Minato-ku, Tokyo (JP); Yukihiro IWANAGA, Minato-ku, Tokyo (JP); Masayuki WADA, Minato-ku, Tokyo (JP); Keiichi SAKAMOTO, Minato-ku, Tokyo (JP); Masahito WATANABE, Minato-ku, Tokyo (JP); Hidekazu KONDO, Minato-ku, Tokyo (JP); Koichi SAITO, Minato-ku, Tokyo (JP)

(21) Appl. No.: 18/860,830

(22) PCT Filed: Oct. 6, 2023
(86) PCT No.: PCT/JP2023/036611

§ 371 Date: Oct. 28, 2024

(30) Foreign Application Priority Data
Oct. 11, 2022 (JP) 2022-163410

(51) Int. Cl. H01L 21/683; H01L 21/78

(52) U.S. Cl. CPC H01L 21/6835; H01L 21/78; H01L 2221/68327; H01L 2221/6834; H01L 2221/68381

(57) ABSTRACT

A method for producing a semiconductor device is disclosed. The method for producing a semiconductor device includes a resin film forming step of forming a resin film containing a resin in which the molecular weight is reduced by irradiation with light on a semiconductor wafer; a resin film piece—including semiconductor chip manufacturing step of manufacturing a singulated resin film piece—including semiconductor chip by dicing the semiconductor wafer in which the resin film is formed with a dicing blade; and a resin film piece removing step of removing the resin film piece from the resin film piece—including semiconductor chip by irradiating a resin film piece of the resin film piece—including semiconductor chip with light.

### TECHNICAL FIELD

The present disclosure relates to a method for producing a semiconductor device.

### BACKGROUND ART

The semiconductor device is generally produced through the following steps. First, a semiconductor wafer is attached to a dicing tape, and in this state, the semiconductor wafer is singulated into semiconductor chips (dicing step). Thereafter, steps such as a pickup step of picking up a semiconductor chip, and a semiconductor chip bonding step of bonding the picked-up semiconductor chip and a support member or the like by bonding via an adhesive (die-bonding film) or the like are performed to manufacture a semiconductor device.

In the dicing step, a fine cut product (debris) generated by cutting the semiconductor wafer adheres to the circuit formation surface of the semiconductor wafer, and a connection failure may occur in a subsequent step. Therefore, it has been studied to provide a resin film (protective film) on a semiconductor wafer, then perform a dicing step, and remove the resin film (protective film) after dicing (for example, Patent Literatures 1 and 2).

### CITATION LIST

### Patent Literature

Patent Literature 1: JP 2014-172932 A

Patent Literature 2: JP 2018-129365 A

### SUMMARY OF INVENTION

### Technical Problem

An object of the present disclosure is to provide a novel method for producing a semiconductor device including forming a resin film on a semiconductor wafer.

### Solution to Problem

The present disclosure provides methods for producing a semiconductor device of [1] to [3].

[1] A method for producing a semiconductor device, the method including: a resin film forming step of forming a resin film containing a resin in which the molecular weight is reduced by irradiation with light on a semiconductor wafer; a resin film piece—including semiconductor chip manufacturing step of manufacturing a singulated resin film piece—including semiconductor chip by dicing the semiconductor wafer in which the resin film is formed with a dicing blade; and a resin film piece removing step of removing the resin film piece from the resin film piece—including semiconductor chip by irradiating a resin film piece of the resin film piece—including semiconductor chip with light.

[2] The method for producing a semiconductor device according to [1], in which the resin film piece removing step is removing the resin film piece from the resin film piece—including semiconductor chip using an aqueous solvent.

[3] The method for producing a semiconductor device according to [1], in which the resin film piece removing step is irradiating a resin film piece of the resin film piece—including semiconductor chip with light in an aqueous solvent.

### Advantageous Effects of Invention

According to the present disclosure, a novel method for producing a semiconductor device including forming a resin film on a semiconductor wafer is provided. According to the method for producing a semiconductor device of the present disclosure, dissolution of a resin film (protective film) by cooling water (cutting water) can be sufficiently suppressed, and thus the resin film (protective film) can be easily removed.

### BRIEF DESCRIPTION OF DRAWINGS

FIG. 1 is a schematic cross-sectional view illustrating an embodiment of a method for producing a semiconductor device, and FIGS. 1(a), 1(b), 1(c), and 1(d) are views illustrating respective steps.

FIG. 2 is a schematic cross-sectional view illustrating an embodiment of the method for producing a semiconductor device, and FIGS. 2(a), 2(b), 2(c), and 2(d) are views illustrating respective steps.

FIG. 3 is photograph data showing results of a light meltability test (2) of examples.

### DESCRIPTION OF EMBODIMENTS

Hereinafter, the present embodiment is described in detail with reference to the drawings. However, the present disclosure is not limited to the following embodiments. In the following embodiments, the components (including steps and the like) are not essential unless otherwise specified. The same or corresponding portions are denoted by the same reference numerals, and redundant description will be omitted. Further, unless otherwise specified, the positional relationship such as up, down, left, and right is based on the positional relationship illustrated in the drawings. The sizes of components in the drawings are conceptual, and the relative relationship between the sizes of the components is not limited to that illustrated in the drawings.

The same applies to numerical values and ranges thereof in the present disclosure, and the present disclosure is not limited thereto. In the present specification, a numerical range indicated by using “to” indicates a range including numerical values described before and after “to” as a minimum value and a maximum value, respectively. In the numerical ranges described in stages in the present specification, the upper limit value or the lower limit value described in one numerical range may be replaced with the upper limit value or the lower limit value of the numerical range described in another stage. In addition, in the numerical range described in the present specification, the upper limit value or the lower limit value of the numerical range may be replaced with a value shown in examples.

In the present specification, the term “layer” includes a structure having a shape partially formed in addition to a structure having a shape formed on the entire surface when observed as a plan view. In the present specification, the term “step” includes not only an independent step but also a step that cannot be clearly distinguished from other steps as long as an intended action of the step is achieved.

In the present specification, (meth)acrylate means acrylate or methacrylate corresponding thereto. The same applies to other similar expressions such as a (meth)acrylic copolymer.

The components and materials exemplified in the present specification may be used singly or in combination of two or more kinds thereof unless otherwise specified.

### Method for Producing Semiconductor Device

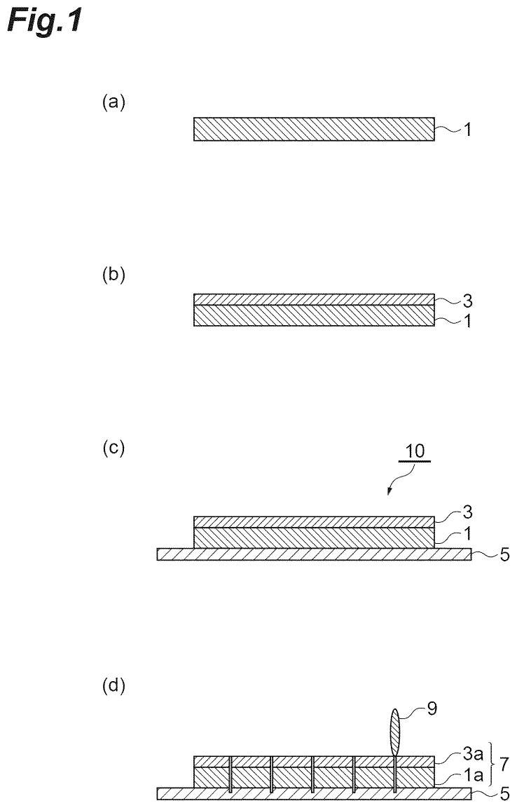

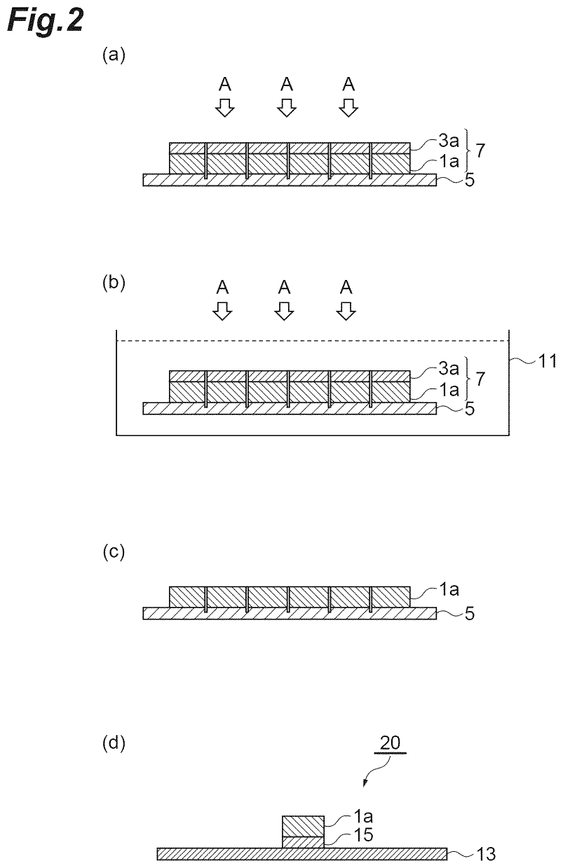

A method for producing a semiconductor device according to an embodiment relates to a method for producing a semiconductor device including forming a resin film (protective film) on a semiconductor wafer. The method for producing a semiconductor device includes a resin film (protective film) forming step, a resin film (protective film) piece—including semiconductor chip manufacturing step, and a resin film (protective film) piece removing step. FIGS. 1 and 2 are schematic cross-sectional views illustrating an embodiment of the method for producing a semiconductor device.

### Resin Film Forming Step

In this step, a resin film 3 containing a resin in which the molecular weight is reduced by irradiation with light (hereinafter, referred to as a “light meltable resin”) is formed on a semiconductor wafer 1. The light meltable resin may be a resin having properties such as deterioration of an elastic modulus and an increase in a loss tangent (tan δ) due to the reduction of the molecular weight by irradiation with light. The light meltable resin is a water-insoluble resin and may be a resin having properties in which the molecular weight is reduced due to the irradiation with light to obtain a water-soluble gel or liquid. The resin film 3 can act as a protective film for preventing fine cut products (debris) generated by cutting the semiconductor wafer from adhering to the circuit formation surface of the semiconductor wafer.

In one embodiment, the light meltable resin may be a reaction product of a compound A having a disulfide bond and two or more thiol groups and a compound B having two or more functional groups capable of reacting with a thiol group. The resin film 3 may further include a photoradical generator in addition to the light meltable resin. The resin film 3 can be formed, for example, by arranging, at a predetermined position, a curable composition containing the compound A, the compound B, the photoradical generator, and, as necessary, a curing accelerator that accelerates the reaction between the compound A and the compound B and curing the curable composition by heating or light irradiation (reacting the compound A and the compound B). At this time, it can be said that the resin film 3 contains a cured product of the curable composition containing the compound A, the compound B, the photoradical generator, and, as necessary, the curing accelerator that accelerates the reaction of the compound A and the compound B. It can be said that the cured product of the curable composition contains a reaction product of the compound A and the compound B and a photoradical generator. The curable composition may be a thermosetting composition that is cured by heating or a photocurable composition that is cured by light irradiation and may be a thermosetting composition according to an embodiment.

According to an embodiment, the curable composition may include the compound A, the compound B, the photoradical generator, and, as necessary, the curing accelerator that accelerates the reaction of the compound A and the compound B.

### (Compound A)

The compound A is a compound having a disulfide bond (—S—S—) and having two or more thiol groups (—SH). The upper limit of the number of thiol groups in the compound A may be, for example, ten or less, eight or less, six or less, or four or less. A component (A) may be, for example, a dithiol compound which is a compound having two thiol groups (—SH). The component (A) may be a high molecular weight component of a polymer or an oligomer. A compound having two thiol groups (—SH) can be regarded as a compound containing two thiol groups and a group containing a disulfide bond and linking the two thiol groups (first linking group).

The molecular weight or number average molecular weight of the compound A may be, for example, 100 to 10,000,000, 200 to 3,000,000, 300 to 1,000,000, 400 to 10,000, or 500 to 5,000. Note that the number average molecular weight is a value in terms of polystyrene using a calibration curve by standard polystyrene by gel permeation chromatography (GPC).

The compound A has one or more (two or more) disulfide bonds in the molecule. The number of disulfide bonds in the compound A may be, for example, 1 to 1,000 or 4 to 50.

The compound A may be a compound having a linear or branched molecular chain and a terminal group and having a disulfide bond in the molecular chain (for example, polymers or oligomers). In this case, the terminal group in the compound A may be a thiol group. When the curable composition contains such a compound as the compound A, the light meltability of the light meltable resin (a reaction product of the compound A and the compound B) tends to be further improved. The molecular chain in the compound A may contain a disulfide bond and a polyether chain or may consist of a disulfide bond and a polyether chain.

The compound A may be, for example, a compound represented by Formula (1): HS—(X—S—S)ₙ₁—X—SH (the compound (1)). In the formula, X represents a polyether chain. A plurality of Xs may be the same as or different from each other. n1 represents an integer of 1 or more. n1 may be, for example, 1 or more or 4 or more or may be 1,000 or less. When the component (A) is a compound represented by Formula (1), a group represented by —(X—S—S)ₙ₁—X— is a first linking group. The compound obtained by extending the chain of the compound (1) may be, for example, a Michael adduct of the compound (1) or a thiourethanized product of the compound (1).

The polyether chain as X may be, for example, a polyoxyalkylene chain. The polyether chain as X may be, for example, a group represented by —X¹—O—X²—O—X³—. X¹ to X³ may each independently be an alkylene group or an alkylene group having one to two carbon atoms (for example, a methylene group or an ethylene group). Examples of the polyether chain as X include —CH₂CH₂—O—CH₂—O—CH₂CH₂—.

Examples of commercially available products of the compound A include Thiokol LP series (dithiol having a disulfide bond, manufactured by Toray Fine Chemicals Co., Ltd.). The compound A can also be obtained by converting a reactive functional group of a compound having a reactive functional group (for example, a carboxy group or a hydroxy group) and a disulfide bond at the terminal into a thiol group. Examples of the compound having a reactive functional group and a disulfide bond at the terminal include 3,3′-dithiodipropionic acid (manufactured by Tokyo Chemical Industry Co., Ltd.), dithiodiethanol, and cystamine.

The content of the compound A may be 15 mass % or more, 25 mass % or more, or 35 mass % or more and may be 80 mass % or less, 70 mass % or less, or 60 mass % or less, based on the total amount of the curable composition (solid content excluding the solvent).

### (Compound B)

The compound B is a compound having two or more functional groups capable of reacting with a thiol group. Examples of the functional group capable of reacting with a thiol group include a cyclic ether group (an oxirane group (an oxiranyl group, an epoxy group), an oxetane group (an oxetanyl group), a tetrahydrofuryl group, a tetrahydropyranyl group, and the like); an isocyanate group; an ethylenically unsaturated group (C═C). The upper limit of the number of functional groups in the compound B may be, for example, ten or less, eight or less, six or less, or four or less.

According to an embodiment, the compound B may be a compound B1 having a polyether chain and having two or more cyclic ether groups. When the curable composition contains the compound B1 as the compound B, the low molecular weight component generated by irradiating the light meltable resin with light has many polyether chains or many hydroxyl groups and tends to exhibit water solubility, so that the low molecular weight component can be removed with an aqueous solvent.

The cyclic ether group may be an oxirane group from the viewpoint of reactivity and availability. That is, the compound B1 is an oxirane compound (epoxy compound) having a polyether chain and having two or more oxirane groups (an oxiranyl group, an epoxy group). Note that in the present specification, the cyclic ether group includes a group having a cyclic ether structure (a structure containing a cyclic ether group). For example, the oxirane group includes a group having an oxirane structure such as a glycidyl group, a glycidyl ether group, or an epoxy cyclohexyl group (a structure containing an oxirane group (an oxiranyl group, an epoxy group)).

The molecular weight or number average molecular weight of the compound B1 may be, for example, 100 to 1,000,000, 100 to 500,000, 100 to 10,000, 150 to 5,000, or 200 to 2,000. Note that the number average molecular weight is a value in terms of polystyrene using a calibration curve by standard polystyrene by gel permeation chromatography (GPC).

When the cyclic ether group of the compound B1 is an oxirane group (an oxiranyl group, an epoxy group), the epoxy equivalent of the component (B) may be 50 to 2,000 g/eq, 80 to 1,500 g/eq, or 100 to 1,000 g/eq.

The compound B1 may be a compound B1a having two cyclic ether groups or a compound B1b having three or more cyclic ether groups. The compound B1a may be a compound having a linear molecular chain and a terminal group and having a polyether chain in the molecular chain (for example, polymers or oligomers). In this case, the terminal group in the compound B1a may be a cyclic ether group. The compound B1a can be regarded as a compound containing two cyclic ether groups and a group containing a polyether chain and linking the two cyclic ether groups (second linking group). The compound B1b may be a compound having one or more cyclic ether groups as a side chain or a substituent of the second linking group in the compound B1a. The compound B1 may contain both the compound B1a and the compound B1b because the compound can further shorten the curing time and can further improve the light meltability and water solubility.

The compound B1a may be a compound having a linear molecular chain and a terminal group and having a polyether chain in the molecular chain (for example, polymers or oligomers). In this case, the terminal group in the compound B1a may be a cyclic ether group. When the compound B is the compound B1a, a low molecular weight component generated by irradiating the light meltable resin with light tends to be easily removed with an aqueous solvent. The polyether chain as a molecular chain may have a substituent such as a hydroxyl group or an alkyl group which may have a hydroxyl group. The molecular chain in the compound B1a may contain a polyether chain or may consist of a polyether chain.

The compound B1a may be, for example, a compound represented by Formula (2): Z—(Y)ₙ₂—Z (the compound (2)). In the formula, Y represents a polyether chain, and Z represents a cyclic ether group. A plurality of Zs may be the same as or different from each other. n2 represents an integer of 1 or more. n2 may be, for example, 1 or more or 2 or more or may be 1,000 or less. When the compound B1a is the compound (2), the group represented by —(Y)ₙ₂— is the second linking group.

The polyether chain as Y may be, for example, a polyoxyalkylene chain. The polyether chain as Y may be, for example, a group represented by —Y¹—O—Y²—O—Y³—. Y¹ to Y³ may each independently be an alkylene group or an alkylene group having one to three carbon atoms (for example, a methylene group, an ethylene group, or a propylene group). Examples of the polyether chain as Y include —CH₂CH₂—O—CH₂—CH₂—O—CH₂CH₂—.

Examples of commercially available products of the compound B1a include Denacol EX series (EX-850, EX-851, EX-821, EX-830, EX-832, EX-841, EX-861, EX-920, manufactured by Nagase ChemteX Corporation).

The compound B1b may be a compound having one or more cyclic ether groups as a side chain of the second linking group (a polyether chain as Y) in the compound B1a.

Examples of commercially available products of the compound B1b include Denacol EX series (EX-614B, EX-313, EX-512, EX-521,manufactured by Nagase ChemteX Corporation).

The mass ratio of the content of the compound B1b to the total amount of the contents of the compound B1a and the compound B1b (a content (mass) of the compound B1b/a total amount (mass) of the contents of the compound B1a and the compound B1b) may be 0.01 to 0.40. When the mass ratio is 0.01 or more, the curing time of the curable composition tends to be further shortened, and when the mass ratio is 0.40 or less, the light meltability and the water solubility tend to be further improved. The mass ratio may be 0.02 or more or 0.03 or more and may be 0.35 or less, 0.30 or less, 0.25 or less, 0.20 or less, 0.15 or less, or 0.10 or less.

The content of the compound B may be 10 mass % or more, 20mass % or more, or 30 mass % or more and may be 60 mass % or less, 50 mass % or less, or 40 mass % or less, based on the total amount of the curable composition (solid content excluding the solvent).

The ratio of the total number of moles of thiol groups in the compound A to the total number of moles of functional groups in the compound B may be, for example, 0.90 or more or 0.95 or more and may be 1.10 or less or 1.05 or less.

### (Photoradical Generator)

The photoradical generator is a component that generates radicals by light irradiation. As the photoradical generator, for example, a component used as a photopolymerization initiator can be used. Examples of the photoradical generator include an intramolecular cleavage type photoradical polymerization initiator in which the material itself is photocleaved by light irradiation to generate two radicals.

Examples of the intramolecular cleavage type photoradical generator include a benzyl ketal-based photoradical generator, an α-aminoalkylphenone-based photoradical generator, an α-hydroxyalkylphenone-based photoradical generator, an α-hydroxyacetophenone-based photoradical generator, and an acylphosphine oxide-based photoradical generator.

Examples of the benzyl ketal-based photoradical generator include 2,2-dimethoxy-1,2-diphenylethane-1-one (Omnirad 651).

Examples of the α-aminoalkylphenone-based photoradical generator include 2-benzyl-2-dimethylamino-1-(4-morpholinophenyl)-butanone-1 (Omnirad 369), 2-methyl-1-[4-(methylthio) phenyl]-2morpholinopropane-1-one (Omnirad 907), and 2-dimethylamino-2-(4-methyl-benzyl)-1-(4-morpholine-4-yl-phenyl)-butane-1-one (Omnirad 379EG).

Examples of the α-hydroxyalkylphenone-based photoradical generator include 1-hydroxy-cyclohexyl-phenyl-ketone (Omnirad 184).

Examples of the α-hydroxyacetophenone-based photoradical generator include 2-hydroxy-1-{4-[4-(2-hydroxy-2 methyl-propionyl)-benzyl]-phenyl}-2 methyl-propane-1-one (Omnirad 127), and 2-hydroxy-2-methyl-1-phenyl-propane-1-one (Omnirad 1173).

Examples of the acylphosphine oxide-based photoradical generator include 2,4,6-trimethylbenzoyl-diphenyl-phosphine oxide (Omnirad TPO H), and bis(2,4,6-trimethylbenzoyl)-phenylphosphine oxide (Omnirad 819).

The content of the photoradical generator may be 1 mass % or more, 3 mass % or more, or 5 mass % or more and may be 30 mass % or less, 20 mass % or less, or 15 mass % or less, based on the total amount of the curable composition (solid content excluding the solvent).

The ratio of the number of moles of the photoradical generator to the number of moles of the compound A (the number of moles of the photoradical generator/the number of moles of the compound A) may be 0.1 or more, 0.2 or more, or 0.3 or more because the light softening properties are further improved.

### (Curing Accelerator)

The curing accelerator is a component for accelerating the reaction of the compound A and the compound B and includes a component functioning as a catalyst of the curing reaction (catalytic curing agent). Examples of the curing accelerator include an amine compound, an imidazole derivative, quaternary ammonium salt, organometallic salt, and a phosphorus compound.

Examples of the amine compound include dicyandiamide, trimethylamine, triethylamine, tripropylamine, tributylamine, tri-n-octylamine, dimethylethylamine, dimethylpropylamine, dimethylbutylmian, dimethyl-n-octylamine, 1,4-diazabicyclo[2.2.2]octane, 1,8-diazabicyclo[5.4.0]undec-7-ene, benzyldimethylamine, 4-methyl-N,N-dimethylbenzylamine, 2,4,6-tris(dimethylaminomethyl)phenol, and 4-dimethylaminopyridine.

Examples of the imidazole derivative include 1-(1-cyanomethyl)-2-ethyl-4-methyl-1H-imidazole, 2-ethyl-4-methylimidazole, 2-methylimidazole, 2-phenylimidazole, 1-cyanoethyl-2-phenylimidazole, 2-phenyl-4,5-dihydroxymethylimidazole, 2-phenyl-4 methyl-5-hydroxymethylimidazole, 2,4,5-triphenylimidazole, 1-benzyl-2imidazole, 1,2-dimethylimidazole, and 1-benzyl-2-phenylimidazole.

Examples of the quaternary ammonium salt include tetramethylammonium chloride, tetraethylammonium chloride, tetrabutylammonium chloride, benzyltrimethylammonium chloride, benzyltriethylammonium chloride, benzyltributylammonium chloride, tetramethylammonium bromide, tetraethylammonium bromide, tetrabutylammonium bromide, benzyltrimethylammonium bromide, benzyltriethylammonium bromide, tetramethylammonium iodide, tetraethylammonium iodide, tetrabutylammonium iodide, and benzyltributylammonium iodide.

Examples of the organometallic salt include organometallic salts such as bis(2,4-pentanedionato) zinc (II), zinc octylate, zinc naphthenate, cobalt naphthenate, copper naphthenate, iron acetylacetone, nickel octylate, and manganese octylate.

Examples of the phosphorus compound include tetraphenylphosphonium tetra-p-tolylborate, tetraphenylphosphonium tetraphenylborate, triphenylphosphine, tri-p-tolylphosphine, tris (4-chlorophenyl)phosphine, tris (4-methoxyphenyl)phosphine, tris (2,6-dimethoxyphenyl)phosphine, triphenylphosphine triphenylborane, tetraphenylphosphonium dicyanamide, and tetraphenylphosphonium tetra(4-methylphenyl) borate.

The content of the curing accelerator may be 0.01 mass % or more, 0.1 mass % or more, or 0.5 mass % or more and may be 10 mass % or less, 5 mass % or less, or 2 mass % or less, based on the total amount of the curable composition (solid content excluding the solvent).

The curable composition may further include components (other components) that do not correspond to the compound A, the compound B, the photoradical generator, and the curing accelerator. Examples of other components include a plasticizer; a tackiness imparting agent such as tackifier; an antioxidant; a leuco dye; a sensitizer; an adhesion improver such as a coupling agent; a polymerization inhibitor; a light stabilizer; an antifoaming agent; a filler; a chain transfer agent; a thixotropy imparting agent; a flame retardant; a mold release agent; a surfactant; a lubricant; and an additive such as an antistatic agent. As these additives, known additives can be used. When the curable composition contains other components, the total content of the other components may be 0 to 95 mass %, 0.01 to 50 mass %, or 0.1 to 10 mass % based on the total amount of the curable composition.

The curable composition may be used as a varnish of the curable composition diluted with a solvent. Examples of the solvent include aromatic hydrocarbon such as toluene, xylene, mesitylene, cumene, and p-cymene; aliphatic hydrocarbon such as hexane and heptane; cyclic alkane such as methylcyclohexane; cyclic ether such as tetrahydrofuran and 1,4-dioxane; ketone such as acetone, methyl ethyl ketone, methyl isobutyl ketone, cyclohexanone, and 4-hydroxy-4-methyl-2-pentanone; ester such as methyl acetate, ethyl acetate, butyl acetate, methyl lactate, ethyl lactate, and γ-butyrolactone; carbonic acid ester such as ethylene carbonate and propylene carbonate; and amide such as N,N-dimethylformamide, N,N-dimethylacetamide, and N-methyl-2-pyrrolidone (NMP). The content of the solid content in the varnish, that is, the content of components other than the solvent in the varnish may be 10 to 95 mass %, 15 to 70 mass %, or 20 to 50 mass % based on the total amount of the varnish.

The resin film forming step may include, for example, preparing the semiconductor wafer 1 (see FIG. 1(a)) and disposing, on the semiconductor wafer 1, the curable composition containing the compound A, the compound B, and, as necessary, the curing accelerator that accelerates the reaction of the compound A and the compound B, and curing the curable composition to form the resin film 3 containing a cured product of the curable composition (see FIG. 1(b)). It can be said that the resin film 3 contains the reaction product of the compound A and the compound B (light meltable resin) and the photoradical generator.

Examples of the semiconductor wafer 1 include single crystal silicon, polycrystalline silicon, various ceramics, and compound semiconductors such as gallium arsenide. The semiconductor wafer 1 may have a circuit formation surface.

The thickness of the semiconductor wafer 1 may be, for example, 10 to 1,000 μm, 20 to 900 μm, or 30 to 800 μm.

The curable composition can be prepared, for example, by a method including mixing or kneading the respective components Mixing and kneading can be performed by described above. appropriately combining a disperser such as a normal stirrer, a mixer, three rolls, a ball mill, or a bead mill.

The method for disposing the curable composition on the semiconductor wafer is not particularly limited. However, examples thereof include a method in which the curable composition is applied onto the semiconductor wafer 1 using a spin coater, a bar coater, or the like, and a method in which the curable composition is molded into a film, and the molded curable composition film is attached (transferred) to the semiconductor wafer 1. The curable composition film may be in a semi-cured state (B-stage state) before bonding the curable composition film and the semiconductor wafer 1. The curable composition may be disposed, for example, on the circuit formation surface of the semiconductor wafer 1.

The curable composition can form a cured product of the curable composition, for example, by heating. The reaction of the compound A and the compound B proceeds by heating the curable composition. At this time, the curing accelerator can accelerate the reaction. The reaction product (light meltable resin) of the compound A and the compound B may be, for example, a compound (polymer) having a structure represented by the following formula. Meanwhile, the photoradical generator is less involved in the reaction, and the cured product of the curable composition may contain a reaction product (light meltable resin) of the compound A and the compound B and the photoradical generator.

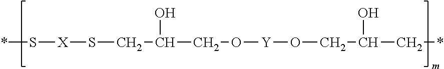

In the formula, X represents a first linking group, and Y represents a second linking group. m represents an integer of 1 or more. m may be, for example, 50 or more, 100 or more, 500 or more, or 1,000 or more. * represents a bond.

The heating temperature of the curable composition may be, for example, 0° C. to 200° C., 30° C. to 150° C., or 60° C. to 100° C. The heating time of the curable composition may be, for example, 0.1 to 168 hours and may be 72 hours or less, 48 hours or less, or 24 hours or less.

The resin film 3 may be in a (completely) cured state (C-stage state). The thickness of the resin film 3 may be, for example, 10 to 1,000 μm, 30 to 500 μm, or 50 to 200 μm.

In this manner, the resin film 3 including the light meltable resin can be formed on the semiconductor wafer 1.

### Resin Film Piece-Including Semiconductor Chip Manufacturing Step

In this step, resin film piece—including semiconductor chips 7 are manufactured by dicing the semiconductor wafer 1 in which the resin film 3 is formed by a dicing blade 9.

The resin film piece—including semiconductor chip manufacturing step may include preparing a laminated body 10 including a dicing tape 5, the semiconductor wafer 1, and the resin film 3 in this order (see FIG. 1(c)) and dicing at least the semiconductor wafer 1 and the resin film 3 in the laminated body 10 by the dicing blade 9 to obtain the singulated resin film piece—including semiconductor chips 7 (see FIG. 1(d)).

Examples of the dicing tape 5 include plastic films such as a polytetrafluoroethylene film, a polyethylene terephthalate film, a polyethylene film, a polypropylene film, a polymethylpentene film, and a polyimide film. Also, the dicing tape may be subjected to a surface treatment such as primer application, a UV treatment, a corona discharge treatment, a polishing treatment, or an etching treatment as necessary. The dicing tape may have tackiness. Such a dicing tape may be a dicing tape obtained by imparting tackiness to the plastic film or a dicing tape obtained by providing a pressure sensitive adhesives layer on one surface of the plastic film. The pressure sensitive adhesive layer may be formed of an ultraviolet-curable or non-ultraviolet-curable pressure sensitive adhesive and is not particularly limited as long as the pressure sensitive adhesive layer has sufficient adhesive strength so that a semiconductor element does not scatter during dicing, and the pressure sensitive adhesive layers known in the related art can be used.

The thickness of the dicing tape 5 may be, for example, 10 to 1,000 μm, 30 to 500 μm, or 50 to 300 μm.

The laminated body 10 can be obtained by attaching the dicing tape 5 to the semiconductor wafer 1 in which the resin film 3 is formed.

Subsequently, in the laminated body 10, at least the semiconductor wafer 1 and the resin film 3 (and a part of the dicing tape 5) are diced by the dicing blade 9 to be singulated into individual pieces. The dicing by the dicing blade 9 can be performed using a commercially available device. The dicing by the dicing blade 9 is performed, for example, on the semiconductor wafer 1 and the resin film 3 in a cutting pattern forming a lattice shape in plan view.

From the viewpoint of suppressing a temperature rise at a contact portion between the semiconductor wafer 1 or the resin film 3 and the dicing blade 9, the dicing by the dicing blade 9 is generally performed while cooling water (cutting water) is poured on the contact portion. Since the light meltable resin is a water-insoluble resin, the resin film 3 can sufficiently suppress dissolution of the resin film due to cooling water (cutting water) and can sufficiently prevent cut products (debris) from adhering to the circuit formation surface of the semiconductor wafer.

In this manner, the semiconductor wafer 1 and the resin film 3 each are singulated, and the resin film piece—including semiconductor chip 7 including semiconductor chips 1a and resin film pieces 3a can be obtained.

The shape of the semiconductor chip 1a in plan view may be, for example, a square or a rectangle. The area of the semiconductor chip la may be, for example, 1 to 250 mm², 4 to 200 mm², or 9 to 150 mm². The length of one side of the semiconductor chip 1a may be 1 mm or more, 2 mm or more, or 3 mm or more and may be 20 mm or less, 18 mm or less, or 15 mm or less. The thickness of the semiconductor chip 1a may be similar to the thickness of the semiconductor wafer 1.

### Resin Film Piece Removing Step

In this step, the resin film piece 3a of the resin film piece—including semiconductor chip 7 is irradiated with light A to remove the resin film piece 3a from the resin film piece—including semiconductor chip 7 (see FIG. 2(a)). Since the light meltable resin included in the resin film piece 3a is reduced in molecular weight due to the irradiation with the light A to obtain a gel or liquid, the resin film pieces 3a can be easily removed from the resin film piece—including semiconductor chip 7.

The mechanism by which the light meltable resin is reduced in molecular weight (melted) is not necessarily clear, but for example, the following mechanism is considered. However, the present invention is not limited to these mechanisms. The light meltable resin includes a compound having a disulfide bond (a reaction product of the compound A and the compound B). When the light meltable resin included in the resin film piece is irradiated with light, disulfide bonds in the light meltable resin are decomposed (cleaved) to generate a thiyl radical. At this time, when the photoradical generator (intramolecular cleavage type photoradical generator) is present, the thiyl radical and the photoradical generator react with each other, and the thiyl radical is capped by the photoradical generator. As a result, it is considered that the molecular weight of the compound having a disulfide bond is reduced, and the cured product is light-softened (light-melted). As another mechanism, it is also conceivable that a light-induced radical caused by a photoradical generator (intramolecular cleavage type photoradical generator) directly reacts with a disulfide bond, to form a light-induced radical-thioether bond and generate a thiyl radical, the thiyl radical reacts with another light-induced radical, the molecular weight of the compound having a disulfide bond itself is reduced, and a photocured product is softened. It can be said that the reaction in which the disulfide bond is cleaved is an irreversible reaction.

The light A with which the resin film piece 3a is irradiated may be, for example, ultraviolet light or visible light. The wavelength of the light A can be appropriately selected according to, for example, the type of the photoradical generator to be used. The wavelength of the light A may be, for example, 150 to 830 nm. The light A may include, for example, light having a wavelength of 405 nm or a wavelength of 365 nm.

The irradiation with the light A can be performed, for example, using a light irradiation device under the condition that the irradiation amount is 1,000 mJ/cm² or more. The irradiation amount can be appropriately set according to, for example, the wavelength of the light A. The irradiation amount may be, for example, 3,000 mJ/cm² or more, 5,000 mJ/cm² or more, or 10,000 mJ/cm² or more and may be 100,000 mJ/cm² or less, 80,000 mJ/cm² or less, or 60,000 mJ/cm² or less.

The irradiation amount means a product of illuminance and irradiation time (seconds). Examples of the light source for irradiation with ultraviolet light or visible light include a low-pressure mercury lamp, an intermediate-pressure mercury lamp, a high-pressure mercury lamp, a metal halide lamp, and an LED lamp.

According to an embodiment, the resin film piece removing step may be removing the resin film piece 3a from the resin film piece—including semiconductor chip 7 using an aqueous solvent. Since the light meltable resin included in the resin film piece 3a is reduced in molecular weight due to the irradiation with the light to obtain a gel or liquid, the resin film piece 3a can be sufficiently removed by being washed with the aqueous solvent.

Examples of the aqueous solvent include water and a mixed solvent of water and a hydrophilic organic solvent. In the mixed solvent of water and the hydrophilic organic solvent, the ratio of water can be, for example, 80 mass % or more. For example, a pH adjusting agent may be added to the aqueous solvent.

The aqueous solvent may be water. Examples of the water include tap water, natural water, purified water, distilled water, ion-exchanged water, pure water, and ultrapure water (Milli-Q water or the like). The Milli-Q water means ultrapure water obtained by a Milli-Q water manufacturing device of Merck Millipore (Merck). Since impurities are reduced, the water may be purified water, distilled water, ion-exchanged water, pure water, or ultrapure water.

Examples of the hydrophilic organic solvent include alcohols such as methanol, ethanol, 2-propanol, and 1,2-propanediol; and glycol ether such as ethylene glycol monomethyl ether, propylene glycol monomethyl ether, ethyl cellosolve, propylene glycol monopropyl ether, propylene glycol monoisopropyl ether, butyl cellosolve, ethylene glycol monoisobutyl ether, propylene glycol monobutyl ether, diethylene glycol dimethyl ether, diethylene glycol diethyl ether, and dipropylene glycol monomethyl ether.

Examples of the pH adjusting agent include inorganic acid, inorganic base, organic acid, and organic base. Examples of the inorganic acid include nitric acid, sulfuric acid, hydrochloric acid, phosphoric acid, and boric acid. Examples of the inorganic base include sodium hydroxide, potassium hydroxide, and calcium hydroxide. Examples of the organic acid include formic acid, acetic acid, propionic acid, butyric acid, acrylic acid, benzoic acid, and picolinic acid. Examples of the organic base include primary amine, secondary amine, tertiary amine, tetramethylammonium hydroxide, tetraethylammonium hydroxide, and an imidazole-based compound.

According to an embodiment, the resin film piece removing step may be irradiating the resin film pieces 3a with the light A from the resin film piece—including semiconductor chip 7 in an aqueous solvent 11 (see

FIG. 2(b)). The light meltable resin included in the resin film piece 3a is reduced in molecular weight due to the irradiation with the light to obtain a gel or liquid. Therefore, by irradiating the resin film pieces 3a with the light A in the aqueous solvent 11, a gel or liquid flows out to the aqueous solvent 11, so that the resin film pieces 3a can be efficiently removed.

In this manner, the plurality of semiconductor chips 1a in which adhesion of cut products (debris) is sufficiently suppressed can be obtained from the semiconductor wafer 1 (see FIG. 2(c)).

The method for producing the semiconductor device according to the present embodiment may further include an ultraviolet irradiation step of irradiating the pressure sensitive adhesive layer of the dicing tape 5 with ultraviolet light, a pickup step of picking up the semiconductor chip 1a, and a semiconductor chip bonding step of bonding the picked-up semiconductor chip 1a and a support member 13 via an adhesive layer 15 (die-bonding film or the like) by thermocompression bonding, a thermal curing step of thermally curing the adhesive layer 15, and the like.

### Ultraviolet Irradiation Step

When the pressure sensitive adhesive layer of the dicing tape 5 is configured with an ultraviolet curable pressure sensitive adhesive, the method for producing the semiconductor device may include the ultraviolet irradiation step. In this step, the pressure sensitive adhesive layer is irradiated with ultraviolet light. In the ultraviolet irradiation, the wavelength of the ultraviolet light may be 200 to 400 nm. In the ultraviolet irradiation condition, the illuminance and the irradiation amount may be in a range of 30 to 240 mW/cm² and a range of 50 to 500 mJ/cm², respectively.

### Pickup Step

In this step, the semiconductor chip 1a pushed up by the needle from the dicing tape 5 side is sucked by the suction collet and picked up from the dicing tape 5 while separating the singulated semiconductor chips 1a from each other.

The ultraviolet irradiation step and the pickup step may be performed after the resin film piece removing step or may be performed before the resin film piece removing step.

### Semiconductor Chip Bonding Step

In this step, the picked-up semiconductor chip 1a and a support member 13 are bonded to each other by thermocompression bonding via an adhesive layer 15 (die-bonding film or the like). As the die-bonding film, a die-bonding film used in the art can be used. The plurality of semiconductor chips 1a may be bonded to the support member 13.

The heating temperature in the thermocompression bonding may be, for example, 80° C. to 160° C. The load in thermocompression bonding may be, for example, 5 to 15 N. The heating time in the thermocompression bonding may be, for example, 0.5 to 20 seconds.

### Thermal Curing Step

In this step, the adhesive layer 15 is thermally cured. The heating temperature can be appropriately changed depending on the constituents of the die-bonding film. The heating temperature may be, for example, 60° C. to 200° C., 90° C. to 190° C., or 120° C. to 180° C. The heating time may be 30 minutes to five hours, one to three hours, or two to three hours. The temperature or the pressure may be stepwise changed.

In this manner, a semiconductor device 20 (see FIG. 2(d)) including the semiconductor chip 1a, the support member 13 on which the semiconductor chip 1a is mounted, and the adhesive layer 15 provided between the semiconductor chip 1a and the support member 13 and bonding the semiconductor chip 1a and the support member 13 can be produced.

### EXAMPLES

Hereinafter, the present disclosure is specifically described with reference to examples, but the present disclosure is not limited to these examples.

### Preparation of Compound

The following compounds were prepared.

### Compound A:

(A-1) Thiokol LP-3 (Dithiol compound, manufactured by Toray Fine Chemicals Co., Ltd.)

### Compound B:

(B1a-1) Denacol EX-841 (Oxirane compound, number of oxirane groups: 2, manufactured by Nagase ChemteX Corporation, epoxy equivalent: 372 g/eq)
(B1b-1) Denacol EX-512 (Oxirane compound, number of oxirane groups: 4, manufactured by Nagase ChemteX Corporation, epoxy equivalent: 168 g/eq)

### Photoradical Generator:

(C-1) Omnirad651 (2,2-dimethoxy-1,2-diphenylethane-1-one (manufactured by IGM Resins B. V.)

### Curing Accelerator:

(D-1) DMP-30 (2,4,6-tris (dimethylaminomethyl) phenol)

### Preparation of Curable Composition

To a 125-mL ointment vessel, components and amounts (unit: part by mass) of the compound A and the curing accelerator shown in Table 1 were added, and the mixture was mixed at 2,000 rpm for 90 seconds using a rotation-revolution stirrer (Product Name: Awatori Rentaro ARE-310, manufactured by THINKY CORPORATION) and then heated at 90° C. for 15 minutes. After cooling, the compound B and the curing accelerator were added, and the mixture was stirred at 2,000 rpm for 90 seconds using the rotation-revolution stirrer to obtain curable compositions of Producing Examples 1 and 2.

TABLE 1

| | | | Producing | Producing |
|---|---|---|---|---|
| | | | Example 1 | Example 2 |
| Compound A | (A-1) | | 47.36 | 47.36 |
| Compound B | (B1) | B1a-1) | 39.94 | 35.33 |
| | | (B1b-1) | 3.88 | 3.49 |

| | | | |
|---|---|---|---|
| Photoradical generator | (C-1) | 12.97 | 12.97 |
| Curing accelerator | (D-1) | 0.85 | 0.85 |

### Preparation of Laminated Body

Using the curable compositions of Producing Examples 1 and 2, a resin film was formed on a silicon wafer. The curable composition was applied with a bar coater, and an 8-inch silicon wafer (thickness: 200 μm) at 25° C. was spin-coated under the conditions of 500 rpm for 5 seconds and then 2,000 rpm for 30 seconds and heated for 24 hours under a nitrogen atmosphere in a dryer set at 100° C. to form a resin film having a thickness of 70 μm on the silicon wafer. Next, a dicing tape was attached to a surface of the silicon wafer on a side opposite to the resin film to manufacture laminated bodies of Examples 1 and 2 having the dicing tape, the silicon wafer, and the resin film in this order.

### Dicing Resistance Test

A dicing resistance test was performed using a dicing saw (DISCO Corporation, Product Name: DFD6361) and dicing blades (DISCO Corporation, Product Name: Z1: ZH05-SD2000-N1-110FF, Z2: ZH05-SD2000-N1-110EE). As a cutting method, a step cutting method was employed, and Z1 (first cutting) was set to the spindle rotation of 40,000 rpm, the feed speed of 50 mm/sec, and the blade height of 200 μm. Z2 (second cut) was set to the spindle rotation of 40,000 rpm, the feed speed of 50 mm/sec, and the blade height of 80 μm. Also, the amount of cooling water was 1.0 L/min. Under such conditions, the silicon wafer on which the protective layer was formed was diced so that the chip size was 5 mm in length and 5 mm in width, and the resin film piece—including semiconductor chips of Examples 1 and 2 were manufactured on the dicing tape. In the resin film piece—including semiconductor chips according to Examples 1 and 2, the vicinity of the intersection of the cutting patterns of the resin film was observed with a microscope, and the case where the resin film was not peeled was evaluated as “A” to be satisfactory, and the case where the resin film was peeled was evaluated as “B”. The results are shown in Table 2.

### Light Meltability Test (1)

The resin film piece—including semiconductor chips of Examples 1 and 2 obtained in the dicing resistance test were picked up from the dicing tape, and a light meltability test was performed using the resin film piece—including semiconductor chips of Examples 1 and 2. The resin film piece—including semiconductor chip was immersed in a water tank to which pure water was added, and the resin film piece of the resin film piece—including semiconductor chip was irradiated with light (LED light having a wavelength of 365 nm). A UV irradiation device (manufactured by Panasonic Industrial Devices SUNX Co., Ltd., power source: AicureUJ30, 365 nmLED head: ANUJ6186) was used for light irradiation. As irradiation conditions, a light receiver for 365 nm was used with an illuminance meter UIT-250 (manufactured by Ushio Inc.). Light irradiation was performed at an illuminance of 1,000 mW/cm² for 60 seconds, and the exposure amount was adjusted to 60,000 mJ/cm². After the irradiation with light, the semiconductor chip was allowed to stand in the water tank for 15 minutes and then was observed. A case where the resin film piece did not remain on the silicon wafer was evaluated as “A” to be satisfactory, and a case where the resin film piece remained on the silicon wafer was evaluated as “B”. The results are shown in Table 2.

### Light Meltability Test (2)

A light meltability test was performed in the same manner as in the light meltability test (1) except that a sample in which a half of the surface of the resin film piece—including semiconductor chip was shielded by aluminum foil was used. The exposure amount was set to three conditions of 10,000 mJ/cm², 30,000 mJ/cm², and 60,000 mJ/cm².

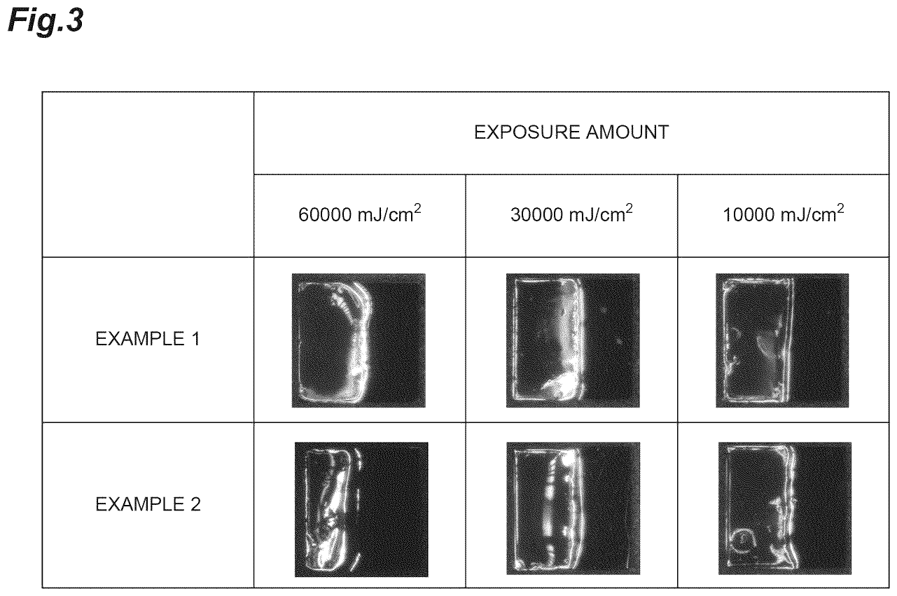

FIG. 3 is photograph data showing results of the light meltability test (2) of examples. When the resin film pieces of the resin film piece—including semiconductor chips of Examples 1 and 2 were irradiated with light, parts of the resin film pieces which were not irradiated with light (parts shielded by an aluminum foil) remained. Meanwhile, in parts of the resin film pieces which were irradiated with light (parts not shielded by an aluminum foil), the resin film pieces were melted, and the resin film pieces did not remain on the silicon wafer.

TABLE 2

| | Example 1 | Example 2 |
|---|---|---|
| Type of curable composition | Producing Example 1 | Producing Example 2 |
| Dicing resistance test | A | A |
| Light meltability test (1) | A | A |

According to the method for producing a semiconductor device of the present disclosure, dissolution of a resin film (protective film) by cooling water (cutting water) can be sufficiently suppressed, and thus the resin film (protective film) can be easily removed.

### REFERENCE SIGNS LIST

1: semiconductor wafer, 1a: semiconductor chip, 3: resin film, 3a: resin film piece, 5: dicing tape, 7: resin film piece—including semiconductor chip, 9: dicing blade, 10: laminated body, 11: aqueous solvent, 13: support member, 15: adhesive layer, 20: semiconductor device

1. A method for producing a semiconductor device, the method comprising:
a resin film forming step of forming a resin film comprising a resin in which the molecular weight is reduced by irradiation with light on a semiconductor wafer;
a resin film piece—including semiconductor chip manufacturing step of manufacturing a singulated resin film piece—including semiconductor chip by dicing the semiconductor wafer in which the resin film is formed with a dicing blade; and
a resin film piece removing step of removing the resin film piece from the resin film piece—including semiconductor chip by irradiating a resin film piece of the resin film piece—including semiconductor chip with light.

2. The method for producing a semiconductor device according to claim 1, wherein the resin film piece removing step is removing the resin film piece from the resin film piece—including semiconductor chip using an aqueous solvent.

3. The method for producing a semiconductor device according to claim 1, wherein the resin film piece removing step is irradiating a resin film piece of the resin film piece—including semiconductor chip with light in an aqueous solvent.

4. The method for manufacturing a semiconductor device according to claim 1, wherein the resin in which the molecular weight is reduced by irradiation with light is a reaction product of a compound A having a disulfide bond and two or more thiol groups and a compound B having two or more functional groups capable of reacting with a thiol group.

5. The method for manufacturing a semiconductor device according to claim 4, the resin layer further comprising a photoradical generator.

6. The method for manufacturing a semiconductor device according to claim 1, wherein the first laminated body manufacturing step comprises:
preparing the semiconductor wafer;
disposing a curable composition comprising a compound A having a disulfide bond and two or more thiol groups, a compound B having two or more functional groups capable of reacting with a thiol group, and a photoradical generator, on the semiconductor wafer; and
curing the curable composition to form the resin film comprising a cured product of the curable composition.
